(19) United States
(12) Patent Application Publication
(10) Pub. No.: US 2026/0047049 A1
(43) Pub. Date: Feb. 12, 2026

(54) LIQUID COOLING SYSTEM, RACK MODULE AND LIQUID COOLING CONTROL METHOD

(71) Applicant: Wiwynn Corporation, New Taipei City (TW)

(72) Inventors: TZU-TING WANG, New Taipei City (TW); Cheng-An Chen, New Taipei City (TW)

(21) Appl. No.: 19/086,295

(22) Filed: Mar. 21, 2025

(30) Foreign Application Priority Data
Aug. 9, 2024 (TW) 113130000

(51) Int. Cl. H05K 7/20; G01M 3/04

(52) U.S. Cl. CPC H05K 7/20281; G01M 3/04; H05K 7/20272; H05K 7/20781

(57) ABSTRACT

A liquid cooling system includes a fluid driver, a plurality of liquid cooling units, a plurality of liquid cooling units, a plurality of detectors and a controller. The liquid cooling units selectively communicate with the fluid driver. The detectors are configured to detect communication states of the liquid cooling units and the fluid driver, respectively. The controller is electrically connected to the fluid driver and the detectors. The controller is configured to adjust a flow rate of a coolant output by the fluid driver according to the communication states.

### CROSS-REFERENCE TO RELATED APPLICATIONS

This non-provisional application claims priority under 35 U.S.C. § 119(a) on Patent Application No(s). 113130000 filed in Taiwan, R.O.C. on Aug. 9, 2024, the entire contents of which are hereby incorporated by reference.

### TECHNICAL FIELD

The disclosure relates to a liquid cooling system, a rack module and a liquid cooling control method.

### BACKGROUND

Nowadays, servers in a rack are cooled via liquid cooling means, and a fluid driver located in the rack or outside the rack is generally used to drive a coolant to flow through the servers. However, a flow rate of the coolant output by the fluid driver is manually set by observing the quantity of the servers in the rack. When the quantity of the servers in the rack is changed, the flow rate of the coolant output by the fluid driver is unable to be automatically adjusted correspondingly, but is required to be adjusted manually, which causes inconvenience issue. As a result, how to address the aforementioned issue is one of the topics in this field.

### SUMMARY

One embodiment of the disclosure provides a liquid cooling system. The liquid cooling system includes a fluid driver, a plurality of liquid cooling units, a plurality of liquid cooling units, a plurality of detectors and a controller. The liquid cooling units selectively communicate with the fluid driver. The detectors are configured to detect communication states of the liquid cooling units and the fluid driver, respectively. The controller is electrically connected to the fluid driver and the detectors. The controller is configured to adjust a flow rate of a coolant output by the fluid driver according to the communication states.

Another embodiment of the disclosure provides a rack module. The rack module includes a rack, a plurality of servers and a liquid cooling system. The servers are slidably disposed in the rack. The liquid cooling system is disposed in the rack and includes a fluid driver, a plurality of liquid cooling units, a plurality of detectors and a controller. The liquid cooling units are disposed in the servers and selectively communicate with the fluid driver. The detectors are configured to detect communication states of the liquid cooling units and the fluid driver, respectively. The controller is electrically connected to the fluid driver and the detectors. The controller is configured to adjust a flow rate of a coolant output by the fluid driver according to the communication states.

Still another embodiment of the disclosure provides a liquid cooling control method. The liquid cooling control method includes detecting communication states of a fluid driver and liquid cooling units in a plurality of servers via a plurality of detectors so as to produce at least one activation signal when the liquid cooling unit in at least one of the servers communicates with the fluid driver, and determining whether a quantity of the at least one activation signal increases or decreases. If yes, increasing or decreasing a flow rate of a coolant output by the fluid driver. If no, maintaining the flow rate of the coolant output by the fluid driver.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a partial cross-sectional view of a rack module according to a first embodiment of the disclosure;

FIG. 2 is a block diagram of a part of a liquid cooling system in FIG. 1;

FIG. 3 is a flow chart of a liquid cooling control method cooperated with the rack module in FIG. 1;

FIG. 4 shows all of liquid cooling units are assembled with a manifold in FIG. 1;

FIG. 5 is a partial cross-sectional view of a server and a liquid cooling system according to a second embodiment of the disclosure;

FIG. 6 is a partial cross-sectional view of a server and a liquid cooling system according to a third embodiment of the disclosure;

FIG. 7 is a partial perspective view of a server and a liquid cooling system according to a fourth embodiment of the disclosure;

FIG. 8 is a partial cross-sectional view of a liquid cooling unit and a manifold in FIG. 7;

FIG. 9 is a partial cross-sectional view of the liquid cooling unit and the manifold in FIG. 7 when they are assembled with each other;

FIG. 10 is a front view of the manifold, a detector, a leakage receiving component and a leakage detecting component in FIG. 9;

FIG. 11 is a partial perspective view of a server and a liquid cooling system according to a fifth embodiment of the disclosure;

FIG. 12 is a partial side view of the server and the liquid cooling system in FIG. 11 when a liquid cooling unit and a manifold are assembled with each other;

FIG. 13 is a partial perspective view of a server and a liquid cooling system according to a sixth embodiment of the disclosure; and

FIG. 14 is a partial side view of the server and the liquid cooling system in FIG. 13 when a liquid cooling unit and a manifold are assembled with each other.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

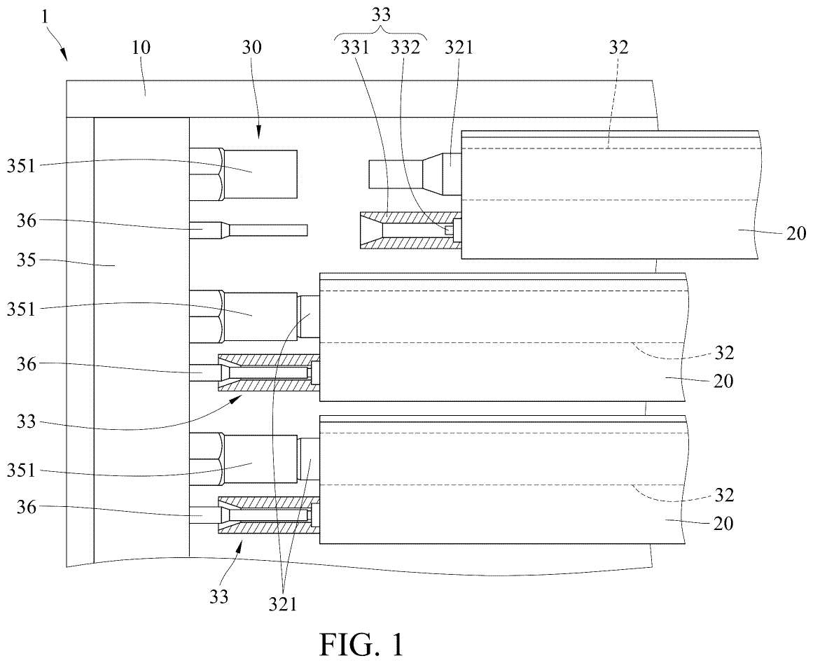

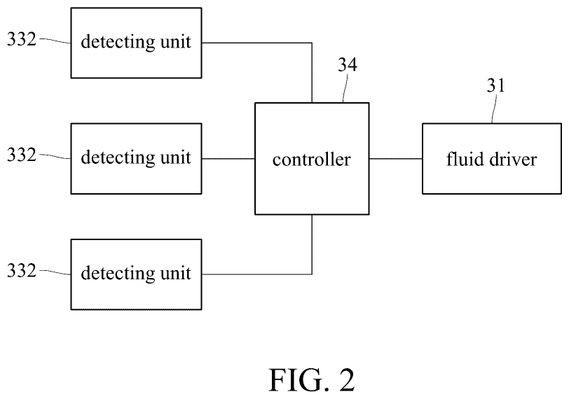

Referring to FIGS. 1 and 2, FIG. 1 is a partial cross-sectional view of a rack module according to a first embodiment of the disclosure, and FIG. 2 is a block diagram of a part of a liquid cooling system in FIG. 1.

In this embodiment, the rack module 1 includes a rack 10, a plurality of servers 20 and a liquid cooling system 30. The servers 20 are slidably disposed in the rack 10. The liquid cooling system 30 is disposed in the rack 10, and includes a fluid driver 31, a plurality of liquid cooling units 32, a plurality of detectors 33 and a controller 34. In addition, the liquid cooling system 30, for example, includes a manifold 35 and a plurality of activation components 36.

The fluid driver 31 communicates with the manifold 35, and the manifold 35 has a plurality of manifold joints 351. The liquid cooling units 32 are respectively disposed in the server 20, and the liquid cooling units 32 are, for example, thermally coupled to heat sources (e.g., CPUs or GPUs) on the motherboards (not shown) of the servers 20 for absorbing heat generated by the heat sources, respectively. Each of the liquid cooling unit 32 has a connection joint 321. The connection joints 321 of the liquid cooling units 32 are selectively assembled with the manifold joints 351 of the manifold 35, respectively. As a result, the fluid driver 31 can drive a coolant to flow into the liquid cooling units 32 via the manifold 35 so as to perform heat exchange with the liquid cooling units 32.

In this embodiment, the liquid cooling system 30 may include another manifold (not shown), the liquid cooling units 32 may communicate with a radiator (not shown) via this manifold, and the radiator communicates with the fluid driver 31. As a result, after the coolant in the liquid cooling units 32 performs heat exchange with the aforementioned heat sources, the coolant can flow into the radiator via this manifold so as to be cooled, and then return to the fluid driver 31.

The detectors 33 are respectively disposed on the liquid cooling units 32, and are respectively located aside the connection joints 321 of the liquid cooling units 32. The structures of the detectors 33 are the same, and thus the following description merely introduces one of them. The detector 33 includes a guide component 331 and a detecting unit 332 located in the guide component 331. The detecting unit 332 is, for example, a contact switch, such as a button switch.

The activation components 36 are disposed on the manifold 35, and the positions of the activation components 36 respectively correspond to the manifold joints 351. In the figure, the activation components 36 are respectively located aside the manifold joints 351 of the manifold 35. The activation components 36 are, for example, pillars, and are respectively configured to be inserted into the guide components 331 of the detectors 33 and press against and activate the detecting units 332 of the detectors 33 for enabling the detecting units 332 to produce signals.

The controller 34 is electrically connected to the detecting units 332 of the detectors 33 and the fluid driver 31; that is, signals can be transmitted between the detectors 33 and the controller 34 and between the fluid driver 31 and the controller 34.

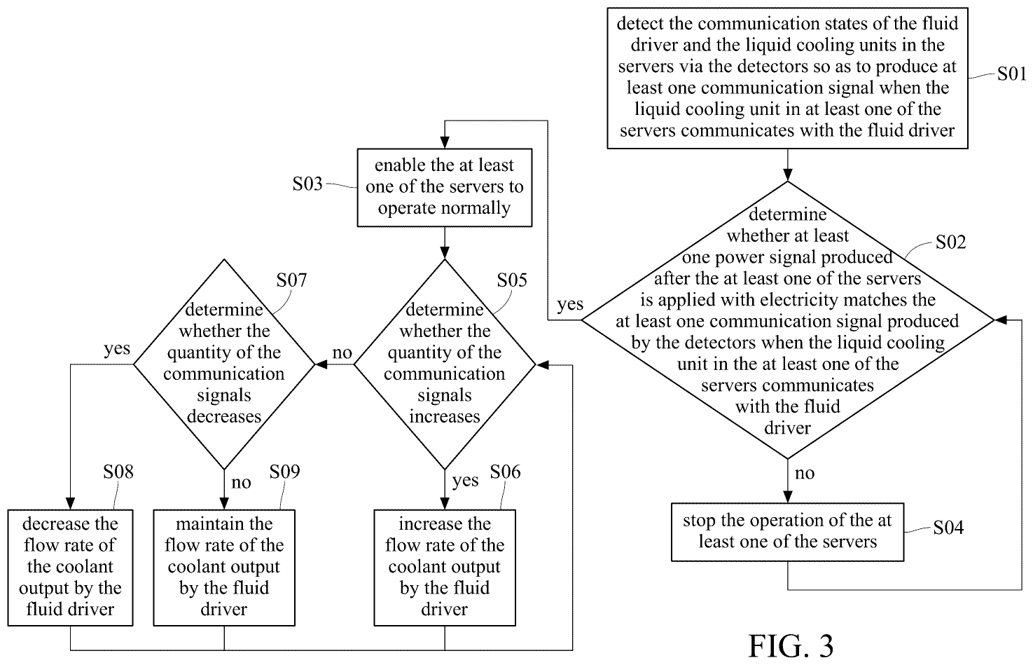

In this embodiment, the detecting units 332 of the detectors 33 are respectively configured to detect communication states of the liquid cooling units 32 and the fluid driver 31, and the controller 34 is configured to adjust a flow rate of the coolant output by the fluid driver 31 according to the communication states. The following paragraphs will introduce a liquid cooling control method cooperated with the rack module 1. Referring to FIG. 3, FIG. 3 is a flow chart of a liquid cooling control method cooperated with the rack module in FIG. 1.

Firstly, a step S01 is performed to detect the communication states of the fluid driver 31 and the liquid cooling units 32 in the servers 20 via the detectors 33 so as to produce at least one activation signal when the liquid cooling unit 32 in at least one of the servers 20 communicates with the fluid driver 31.

For example, as shown in FIG. 2, there are two servers 20 which have been installed in the rack 10 already, and the connection joints 321 of the liquid cooling units 32 therein are assembled with the manifold joints 351 of the manifold 35, such that the liquid cooling units 32 in these two servers 20 communicate with the fluid driver 31 via the manifold 35, and the detecting units 332 of the detectors 33 disposed on these two liquid cooling units 32 are activated by the activation components 36. As a result, these two detecting unit 332 each may produce the activation signal and transmit it to the controller 34, and thus the controller 34 can determine the liquid cooling units 32 in these two servers 20 has been assembled with the manifold 35 so as to communicate with the fluid driver 31 via these two activation signals, thereby setting the flow rate of the coolant output by the fluid driver 31 accordingly.

Then, a step S02 is performed to determine whether at least one power signal produced after the at least one of the servers 20 is applied with electricity matches the at least one activation signal produced by the detectors 33 when the liquid cooling unit 32 in the at least one of the servers 20 communicates with the fluid driver 31. If yes, a step S03 is performed to enable the at least one of the servers 20 to operate normally. If no, a step S04 is performed to stop the operation of the at least one of the servers 20.

For example, the activation signals described in the S01, for example, include identification information (e.g., a serial number) of the servers 20. In addition, after the servers 20 are installed in the rack 10, the servers 20 are applied with electricity. After the servers 20 are provided with electricity, power signals may be transmitted (e.g., by the servers 20) to the controller 34, and the power signals may also include identification information (e.g., a serial number) of the servers 20. Moreover, after the servers 20 are installed in the rack 10, the liquid cooling units 32 in the servers 20 also communicate with the manifold 35. As a result, after the controller 34 compares the power signals with the activation signals, the controller 34 can determine whether the detecting units 332, the activation components 36 and connections between the liquid cooling units 32 in the servers 20 and the manifold 35 are normal or not.

More specifically, assuming that the serial numbers included by the power signals produced after the aforementioned two servers 20 are applied with electricity are respectively “1” and “2”, but the controller 34 merely receives the activation signal including the serial number as “1”, it represents that the detecting unit 332 that produces the activation signal as serial number “2” and the corresponding activation component 36 are abnormal or damaged, or the liquid cooling unit 32 corresponding to this detecting unit 332 is not properly connected to the manifold 35. Therefore, the step S04 is performed to stop the operation of the server 20 where the liquid cooling unit 32 is disposed, and then notify a maintainer to perform maintenance. Then, the step S02 is performed again. In contrast, when the power signals can match the activation signals, the step S03 is performed to enable the servers 20 to operate normally, and then a step of determining whether the quantity of the communication between the liquid cooling units 32 and the manifold 35 is changed is performed, such as a step S05.

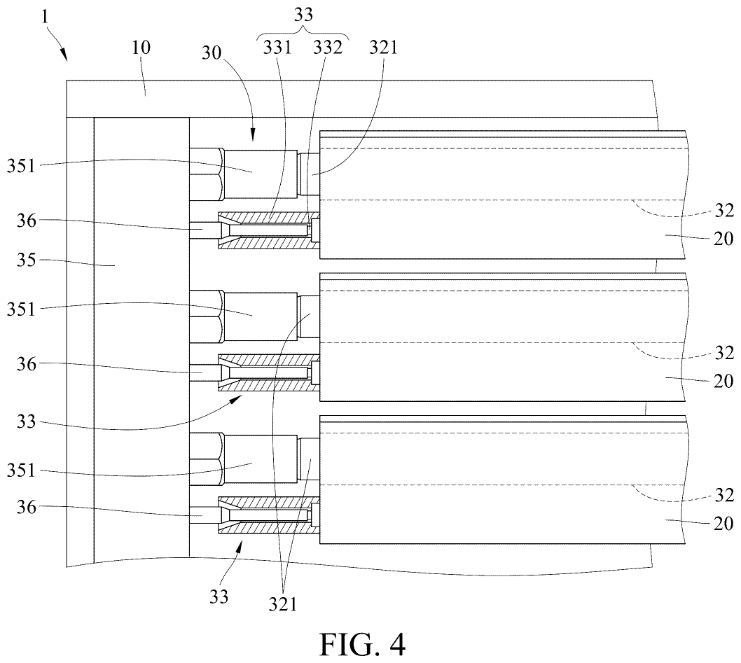

The step S05 is performed to determine whether the quantity of the activation signals increases. If yes, a step S06 is performed to increase the flow rate of the coolant output by the fluid driver 31. For example, referring to FIG. 4, FIG. 4 shows all of liquid cooling units are assembled with a manifold in FIG. 1. When there is another server 20 installed in the rack 10, and the connection joint 321 of the liquid cooling unit 32 therein is assembled with the manifold joint 351 of the manifold 35, the liquid cooling unit 32 in this server 20 communicates with the fluid driver 31 via the manifold 35, and the detecting unit 332 of the detector 33 disposed on this liquid cooling unit 32 is activated by the activation component 36. As a result, the detecting unit 332 produces the activation signal and transmits it to the controller 34. At this moment, the controller 34 determines the quantity of the activation signals increases, and thus knows that the liquid cooling unit 32 in another server 20 is assembled with the manifold 35 and communicates with the fluid driver 31. Therefore, the controller 34 increases the flow rate of the coolant output by the fluid driver 31, such that the coolant entering into the liquid cooling units 32 in these servers 20 can sufficiently perform heat exchange with the liquid cooling units 32.

In contrast, in the step S05, when the quantity of the activation signal does not increase, a step S07 is performed to determine whether the quantity of the activation signals decreases. If yes, a step S08 is performed to decrease the flow rate of the coolant output by the fluid driver 31. For example, as shown in FIG. 1, during the removal of one of the servers 20 from the rack 10, when the connection joint 321 of the liquid cooling unit 32 in this server 20 is detached from the manifold joint 351 of the manifold 35, the activation component 36 is detached from the detecting unit 332 of the detector 33, such that the detecting unit 332 is switched from an activated state to a non-activated stated. At this moment, the activation signal produced by this detecting unit 332 disappears. Therefore, when the controller 34 determines that the quantity of the activation signal decreases, the controller 34 can know the quantity of the liquid cooling units 32 that communicate with the fluid driver 31 decreases, and thus the controller 34 decreases the flow rate of the coolant output by the fluid driver 31.

In the step S07, when the quantity of the activation signals does not decrease, a step S09 is performed to maintain the flow rate of the coolant output by the fluid driver 31.

In this embodiment, the detectors 33 detect the communication states of the liquid cooling units 32 in the servers 20 and the fluid driver 31, and the controller 34 adjusts the flow rate of the coolant output by the fluid driver 31 according to the communication states, which enables the flow rate of the coolant output by the fluid driver 31 to be automatically adjusted according to the quantity of the liquid cooling units 32 communicating with the fluid driver, thereby achieving the automatic adjustment of the flow rate of the coolant.

Note that the steps S02 to S04 are optional and may be omitted in some other embodiments; that is, after the step S01, a step of determining whether the quantity of the communication between the liquid cooling units 32 and the manifold 35 is changed (e.g., the step S05) may be performed directly.

In addition, the step S07 is not restricted to being performed after the step S05. In some other embodiments, the step S07 may be performed before the step S05; that is, the order of the step S05 and the step S07 can be switched.

Note that the communication states of the liquid cooling units 32 in the servers 20 and the fluid driver 31 is not restricted to being detected by the detectors and may be obtained by other means.

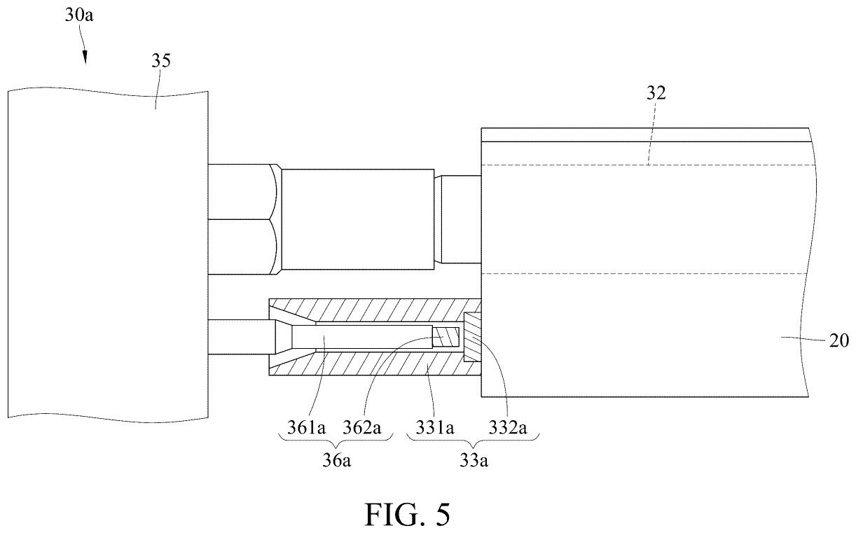

Then, referring to FIG. 5, FIG. 5 is a partial cross-sectional view of a server and a liquid cooling system according to a second embodiment of the disclosure.

The liquid cooling system 30a of this embodiment is similar to the aforementioned liquid cooling system 30 of the first embodiment, the main difference between them is the detector and the activation component, and thus the following paragraph mainly introduces a detector 33a and an activation component 36a of this embodiment while other parts of this embodiment can be referred to the paragraphs of the previous embodiment and will not be repeatedly introduced hereinafter.

In this embodiment, a detecting unit 332a in a guide component 331a of the detector 33a is a reed switch, and the activation component 36a disposed on the manifold 35 includes a pillar 361a and a magnet 362a disposed on one end of the pillar 361a. When the server 20 is installed in the rack 10 (e.g., shown in FIG. 1), and the liquid cooling unit 32 therein is assembled with the manifold 35, the pillar 361a of the activation component 36a is inserted into the guide component 331a of the detector 33a, and the magnet 362a is moved close to the detecting unit 332a, such that the magnetic force provided by the magnet 362a activates the detecting unit 332a so as to enable the detecting unit 332a to produce an activation signal.

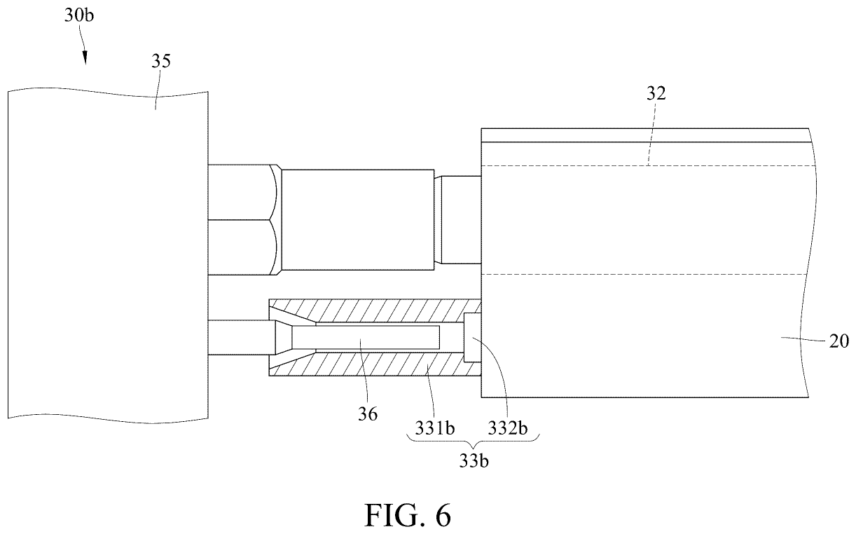

Then, referring to FIG. 6, FIG. 6 is a partial cross-sectional view of a server and a liquid cooling system according to a third embodiment of the disclosure.

The liquid cooling system 30b of this embodiment is similar to the aforementioned liquid cooling system 30 of the first embodiment, the main difference between them is the detector, and thus the following paragraph mainly introduces a detector 33b of this embodiment while other parts of this embodiment can be referred to the paragraphs of the previous embodiment and will not be repeatedly introduced hereinafter.

In this embodiment, a detecting unit 332b in a guide component 331b of the detector 33b is an optical distance sensor. When the server 20 is installed in the rack 10 (e.g., shown in FIG. 1), and the liquid cooling unit 32 therein is assembled with the manifold 35, the activation component 36 is inserted into the guide component 331b of the detector 33b so as to be located close to the detecting unit 332b. Once a distance between the activation component 36 and the detecting unit 332b is smaller than a predetermined value, the detecting unit 332b is activated so as to produce an activation signal.

Note that the guide component 331b of the detector 33b is an optional component and may be omitted in some other embodiments, such that the detecting unit may be exposed to outside. In such a case, the detecting unit is not restricted to being activated by the activation component. In one embodiment, the exposed detecting unit may be activated by the manifold when the detecting unit and the manifold are close enough.

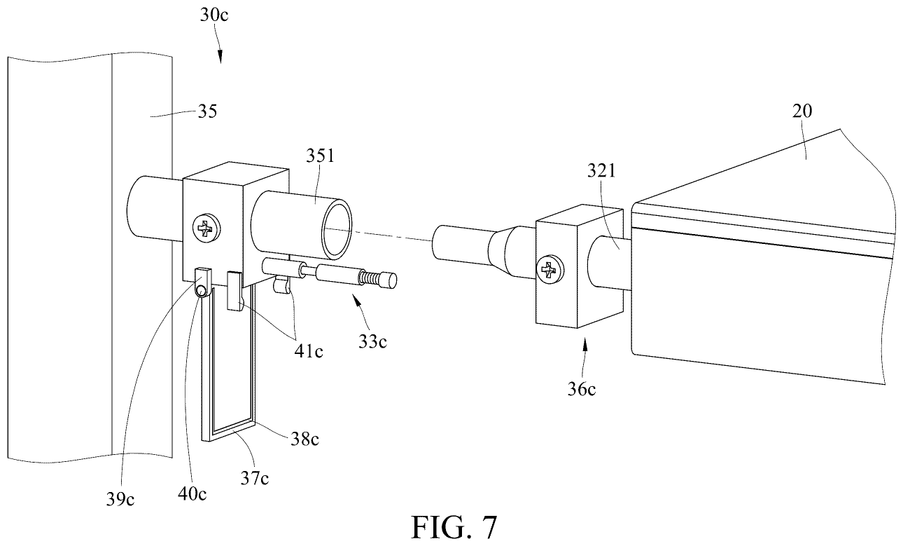

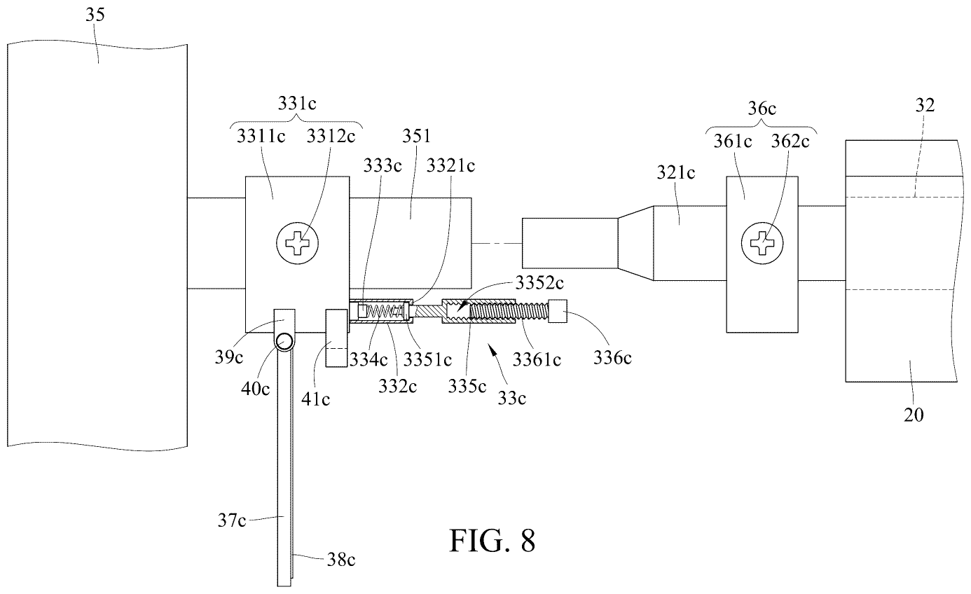

Then, referring to FIGS. 7 and 8, FIG. 7 is a partial perspective view of a server and a liquid cooling system according to a fourth embodiment of the disclosure, and FIG. 8 is a partial cross-sectional view of a liquid cooling unit and a manifold in FIG. 7.

The liquid cooling system 30c of this embodiment is similar to the aforementioned liquid cooling system 30 of the first embodiment, the main difference between them is the detector and the activation component, and thus the following paragraph mainly introduces a detector 33c and an activation component 36c of this embodiment while other parts of this embodiment can be referred to the paragraphs of the previous embodiment and will not be repeatedly introduced hereinafter.

In this embodiment, the detector 33c is disposed on the manifold joint 351 of the manifold 35. For example, the detector 33c includes a mount seat 331c, a guide component 332c, a detecting unit 333c, an elastic component 334c, a movable component 335c and an adjustable extension component 336c.

The mount seat 331c is sleeved on and fixed to the manifold joint 351 of the manifold 35. The mount seat 331c, for example, includes a base 3311c and a fastener 3312c. The base 3311c is sleeved on the manifold joint 351 of the manifold 35. The fastener 3312c is, for example, a screw. The fastener 3312c is screwed into the base 3311c so as to force the manifold joint 351 to tightly press against an inner surface of the base 3311c.

The guide component 332c is, for example, a hollow tube. The guide component 332c is fixed to the base 3311c of the mount seat 331c, and one end of the guide component 332c located farther away from the base 3311c of the mount seat 331c is provided with an inner limiting flange 3321c. The detecting unit 333c is located in the guide component 332c and is located close to the base 3311c of the mount seat 331c. The elastic component 334c is, for example, a compression spring. The elastic component 334c is located in the guide component 332c, and one end of the elastic component 334c is in contact with the detecting unit 333c. One end of the movable component 335c is movably disposed in the guide component 332c and is in contact with another end of the elastic component 334c. The end of the movable component 335c located in the guide component 332c is provided with an outer flange 3351c. The outer flange 3351c is located closer to the base 3311c of the mount seat 331c than the inner limiting flange 3321c, and the outer flange 3351c can be limited by the inner limiting flange 3321c to prevent the movable component 335c from being completely detached from the guide component 332c. In addition, one end of the movable component 335c located farther away from the guide component 332c is provided with a threaded hole 3352c. The adjustable extension component 336c has a threaded portion 3361c. The threaded portion 3361c of the adjustable extension component 336c is screwed into the threaded hole 3352c of the movable component 335c. The adjustable extension component 336c can be rotated to adjust a length that the adjustable extension component 336c protrudes from the movable component 335c.

In this embodiment, the liquid cooling system 30c further includes a leakage receiving component 37c and a leakage detecting component 38c. The leakage receiving component 37c is disposed on the manifold 35 and located below the manifold joint 351 of the manifold 35. For example, the liquid cooling system 30c may further includes two mount structures 39c, a shaft 40c and two holders 41c. The mount structures 39c are disposed on a bottom of the base 3311c of the mount seat 331c, and the leakage receiving component 37c is pivotably disposed on the mount structures 39c via the shaft 40c so as to be pivotable relative to the base 3311c. The holders 41c are disposed on the bottom of the base 3311c of the mount seat 331c for holding the leakage receiving component 37c to be in a horizontal position to receive leakage. The leakage detecting component 38c is, for example, a leakage detection band. The leakage detecting component 38c is disposed on the leakage receiving component 37c for detecting leakage.

In this embodiment, the activation component 36c is sleeved on and fixed to the connection joint 321 of the liquid cooling unit 32. For example, the activation component 36c, for example, includes a base 361c and a fastener 362c. The base 361c of the activation component 36c is sleeved on the connection joint 321 of the liquid cooling unit 32. The fastener 362c is, for example, a screw. The fastener 362c is screwed into the base 361c so as to force the connection joint 321 to tightly press against an inner surface of the base 361c.

As shown in FIG. 8, before the server 20 is installed into the rack 10 (e.g., shown in FIG. 1), one end of the leakage receiving component 37c is required to be moved away from the manifold joint 351 of the manifold 35 so as to place the leakage receiving component 37c to be in a vertical position for preventing the leakage receiving component 37c from interfering with a hand of the maintainer or a tool during the assembly of the manifold joint 351 of the manifold 35 and the connection joint 321 of the liquid cooling unit 32.

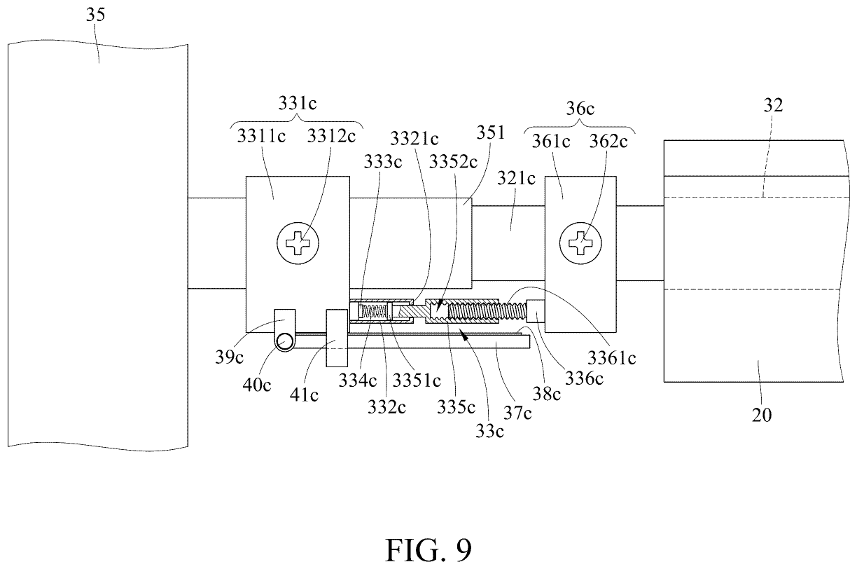

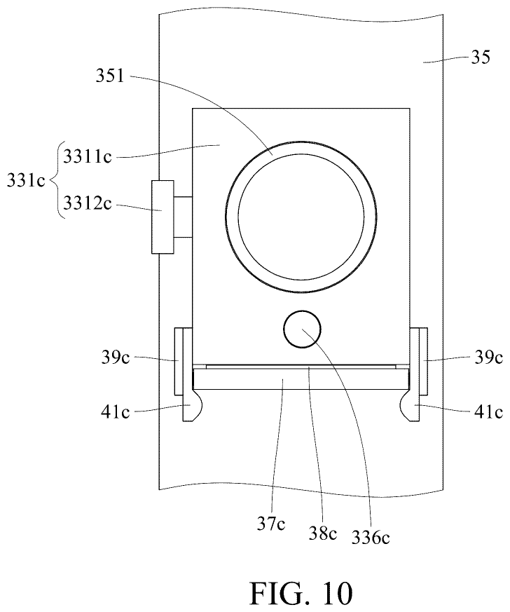

Then, referring to FIGS. 9 and 10, FIG. 9 is a partial cross-sectional view of the liquid cooling unit and the manifold in FIG. 7 when they are assembled with each other, and FIG. 10 is a front view of the manifold, a detector, a leakage receiving component and a leakage detecting component in FIG. 9.

As shown in FIG. 9, when the server 20 is installed in the rack 10, and the liquid cooling unit 32 therein is assembled with the manifold 35, the base 361c of the activation component 36c presses against the movable component 335c via the adjustable extension component 336c so as to force the elastic component 334c to activate the detecting unit 333c, such that the detecting unit 333c produces an activation signal. Then, as shown in FIG. 10, the leakage receiving component 37c is pivoted to be in the horizontal position to be fixed by the holders 41c for receiving leakage.

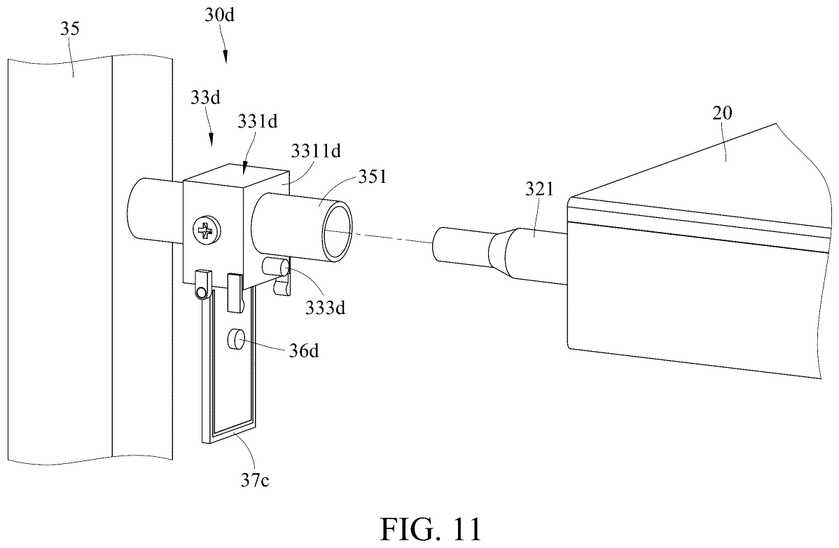

Then, referring to FIG. 11, FIG. 11 is a partial perspective view of a server and a liquid cooling system according to a fifth embodiment of the disclosure.

The liquid cooling system 30d of this embodiment is similar to the aforementioned liquid cooling system 30c of the fourth embodiment, the main difference between them is the detector and the activation component, and thus the following paragraph mainly introduces a detector 33d and an activation component 36d of this embodiment while other parts of this embodiment can be referred to the paragraphs of the previous embodiment and will not be repeatedly introduced hereinafter.

In this embodiment, a detecting unit 333d of the detector 33d is a reed switch, and the detecting unit 333d is exposed to outside from a base 3311d of a mount seat 331d of the detector 33d. The activation component 36d is a magnet, and the activation component 36d is disposed on the leakage receiving component 37c and can be located close to or far away from the detecting unit 333d along with the pivotal movement of the leakage receiving component 37c relative to the base 3311d.

As shown in FIG. 11, before the server 20 is installed in the rack 10 (e.g., shown in FIG. 1), one end of the leakage receiving component 37c is required to be moved away from the manifold joint 351 of the manifold 35 so as to place the leakage receiving component 37c to be in the vertical position for preventing the leakage receiving component 37c from interfering with a hand of the maintainer or a tool during the assembly of the manifold joint 351 of the manifold 35 and the connection joint 321 of the liquid cooling unit 32.

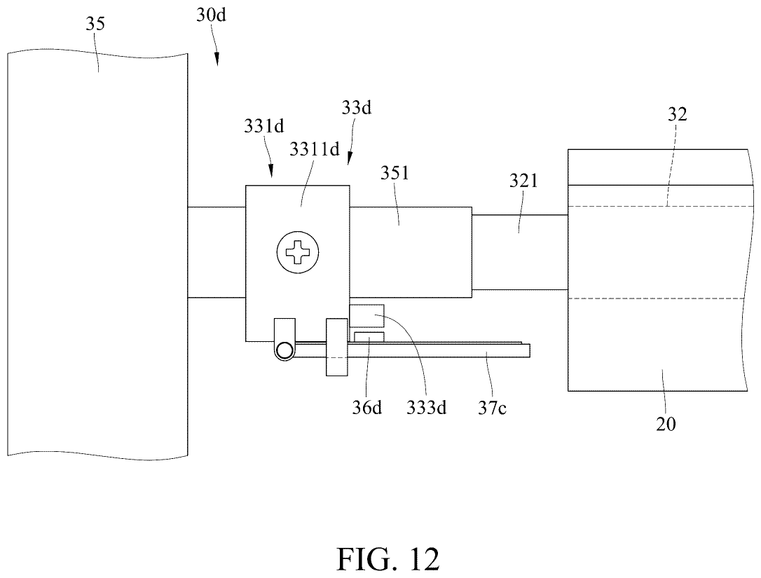

Then, referring to FIG. 12, FIG. 12 is a partial side view of the server and the liquid

cooling system in FIG. 11 when a liquid cooling unit and a manifold are assembled with each other. After the server 20 is installed in the rack 10, and the liquid cooling unit 32 therein is assembled with the manifold 35, the leakage receiving component 37c is pivoted to be in the horizontal position for receiving leakage. At this moment, the activation component 36d is located relative close to the detecting unit 333d of the detector 33d so as to activate the detecting unit 333d to produce an activation signal.

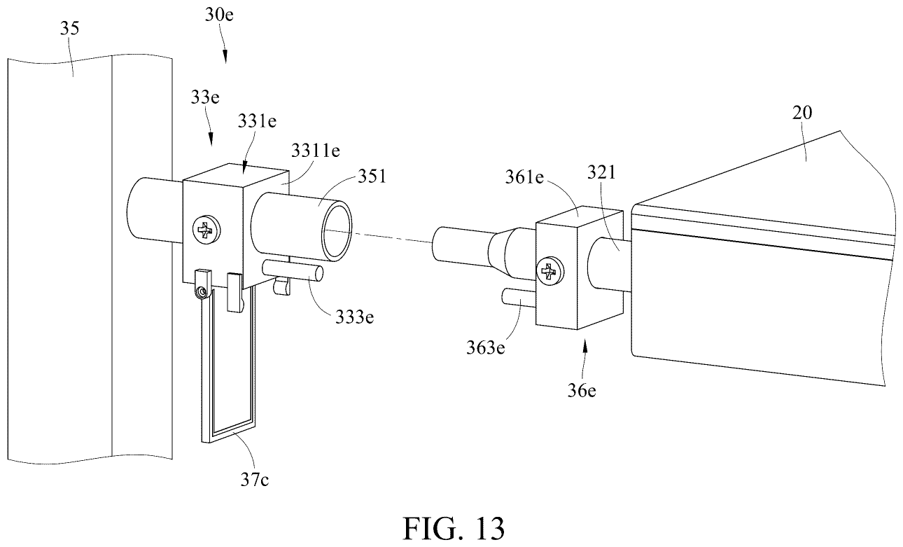

Then, referring to FIG. 13, FIG. 13 is a partial perspective view of a server and a liquid cooling system according to a sixth embodiment of the disclosure.

The liquid cooling system 30e of this embodiment is similar to the aforementioned liquid cooling system 30c of the fourth embodiment, the main difference between them is the detector and the activation component, and thus the following paragraph mainly introduces a detector 33e and an activation component 36e of this embodiment while other parts of this embodiment can be referred to the paragraphs of the previous embodiment and will not be repeatedly introduced hereinafter.

In this embodiment, a detecting unit 333e of the detector 33e is a reed switch, and the detecting unit 333e is exposed to outside from a base 3311e of a mount seat 331e of the detector 33e. The activation component 36e further includes a magnet 363e, and the magnet 363e is disposed on a base 361e of the activation component 36e.

As shown in FIG. 13, before the server 20 is installed in the rack 10 (e.g., shown in FIG. 1), one end of the leakage receiving component 37c is required to be moved away from the manifold joint 351 of the manifold 35 so as to place the leakage receiving component 37c to be in the vertical position for preventing the leakage receiving component 37c from interfering with a hand of the maintainer or a tool during the assembly of the manifold joint 351 of the manifold 35 and the connection joint 321 of the liquid cooling unit 32.

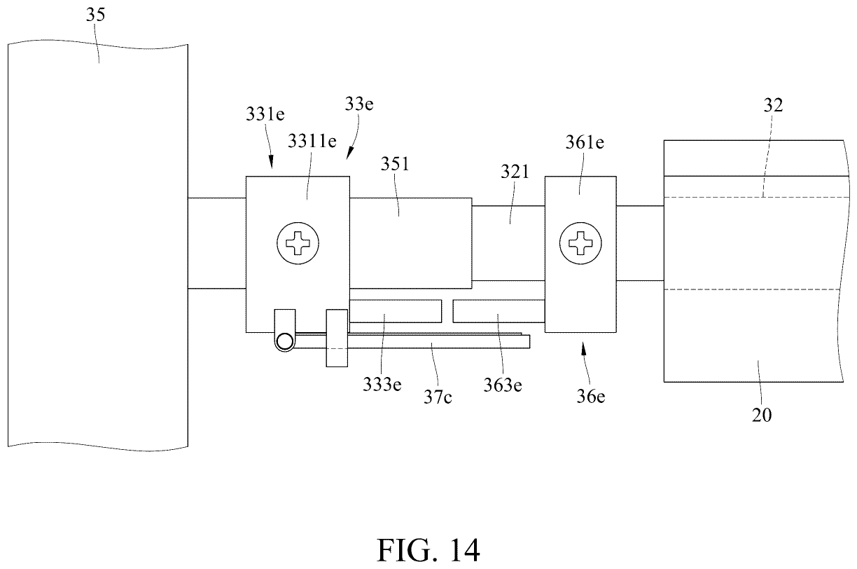

Then, referring to FIG. 14, FIG. 14 is a partial side view of the server and the liquid cooling system in FIG. 13 when a liquid cooling unit and a manifold are assembled with each other. When the server 20 is installed in the rack 10, and the liquid cooling unit 32 therein is assembled with the manifold 35, the magnet 363e of the activation component 36e is located close to the detecting unit 333e for enabling the detecting unit 333e to produce an activation signal. Then, the leakage receiving component 37c is pivoted to be in the horizontal position for receiving leakage.

According to the liquid cooling systems, the rack module and the liquid cooling control method as disclosed in the above embodiments, the detectors detect the communication states of the liquid cooling units in the servers and the fluid driver, and the controller adjusts the flow rate of the coolant output by the fluid driver according to the communication states, which enables the flow rate of the coolant output by the fluid driver can be automatically adjusted according to the quantity of the liquid cooling units communicating with the fluid driver, thereby realizing the automatic adjustment of the flow rate of the coolant.

In addition, the step of determining whether the power signals produced after the servers are applied with electricity match the activation signals produced by the detectors when the liquid cooling units in the servers communicate with the fluid driver can help to determine whether the detecting units, the activation components and the connections between the liquid cooling units in the servers and the manifold are normal or not.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A liquid cooling system, comprising:
a fluid driver;
a plurality of liquid cooling units, selectively communicating with the fluid driver;
a plurality of detectors, configured to detect communication states of the plurality of liquid cooling units and the fluid driver, respectively; and
a controller, electrically connected to the fluid driver and the plurality of detectors, wherein the controller is configured to adjust a flow rate of a coolant output by the fluid driver according to the communication states.

2. The liquid cooling system according to claim 1, further comprising a manifold, wherein the plurality of liquid cooling units selectively communicate with the fluid driver via the manifold, and the plurality of detectors are respectively disposed on the plurality of liquid cooling units or are disposed on the manifold.

3. The liquid cooling system according to claim 2, further comprising a plurality of activation components;
wherein the plurality of detectors are respectively disposed on the plurality of liquid cooling units, and the plurality of activation components are disposed on the manifold; or the plurality of detectors are disposed on the manifold, and the plurality of activation components are respectively disposed on the plurality of liquid cooling units;
wherein at least one of the plurality of detectors is configured to be activated by at least one of the plurality of activation components to produce at least one activation signal when at least one of the plurality of liquid cooling units communicates with the fluid driver.

4. The liquid cooling system according to claim 3, wherein each of the plurality of liquid cooling units has a connection joint, the manifold has a plurality of manifold joints, the connection joints of the plurality of liquid cooling units are selectively assembled with the plurality of manifold joints of the manifold, respectively, the plurality of detectors are respectively disposed on the plurality of liquid cooling units and located aside the connection joints of the plurality of liquid cooling units, and the plurality of activation components are disposed on the manifold and are respectively located aside the plurality of manifold joints of the manifold.

5. The liquid cooling system according to claim 4, wherein each of the plurality of detectors comprises a guide component and a detecting units located in the guide component, and the plurality of activation components are configured to be inserted into the guide components of the plurality of detectors and activate the detecting units, respectively.

6. The liquid cooling system according to claim 5, wherein the detecting units of the plurality of detectors are contact switches or optical distance sensors, and the plurality of activation components are pillars.

7. The liquid cooling system according to claim 5, wherein the detecting units of the plurality of detectors are reed switches, and each of the plurality of activation components comprises a pillar and a magnet disposed on one end of the pillar.

8. The liquid cooling system according to claim 3, wherein each of plurality of liquid cooling units has a connection joint, the manifold has a plurality of manifold joints, the connection joints of the plurality of liquid cooling units are selectively assembled with the plurality of manifold joints of the manifold, respectively, the plurality of detectors are respectively disposed on the plurality of manifold joints of the manifold, and the plurality of activation components are respectively disposed on the connection joints of the plurality of liquid cooling units.

9. The liquid cooling system according to claim 8, wherein each of the plurality of detectors comprises a mount seat, a guide component, a detecting unit, an elastic component and a movable component; in each of the plurality of detectors, the mount seat is sleeved on one of the plurality of manifold joints of the manifold, the guide component is fixed to the mount seat, the detecting unit is located in the guide component, the elastic component is located in the guide component, one end of the elastic component is in contact with the detecting unit, the movable component is movably disposed on the guide component and is in contact with another end of the elastic component; the plurality of activation components are respectively sleeved on and fixed to the connection joints of the plurality of liquid cooling units, the plurality of activation components are configured to press against the movable components of the plurality of detectors for forcing the elastic components to activate the detecting units, respectively.

10. The liquid cooling system according to claim 9, wherein each of the plurality of detectors further comprises an adjustable extension component; in each of the plurality of detectors, the adjustable extension component is movably disposed on one end of the movable component located farther away from the elastic component; the plurality of activation components are configured to press against the movable components via the adjustable extension components for forcing the elastic components to activate the detecting units, respectively.

11. The liquid cooling system according to claim 2, further comprising a plurality of leakage receiving components and a plurality of leakage detecting components, wherein each of the plurality of liquid cooling units has a connection joint, the manifold has a plurality of manifold joints, the connection joints of the plurality of liquid cooling units are selectively assembled with the plurality of manifold joints of the manifold, respectively, the plurality of leakage receiving components are disposed on the manifold and are respectively located below the plurality of manifold joints of the manifold, and the plurality of leakage detecting components are respectively disposed on the plurality of leakage receiving components.

12. The liquid cooling system according to claim 11, wherein the plurality of leakage receiving components are pivotably disposed on the manifold.

13. The liquid cooling system according to claim 12, further comprising a plurality of activation components, wherein the plurality of detectors are respectively disposed on the plurality of manifold joints of the manifold, the plurality of activation components are respectively disposed on the plurality of leakage receiving components, the plurality of activation components are movable to be located relative close to the plurality of detectors along with a pivotal movements of the plurality of leakage receiving components for activating the plurality of detectors, respectively.

14. The liquid cooling system according to claim 1, wherein at least one of the plurality of detectors is configured to produce at least one activation signal when at least one of the plurality of liquid cooling units communicates with the fluid driver, and the controller is configured to adjust the flow rate of the coolant output by the fluid driver according to the at least one activation signal.

15. A liquid cooling control method, comprising:
detecting communication states of a fluid driver and liquid cooling units in a plurality of servers via a plurality of detectors so as to produce at least one activation signal when the liquid cooling unit in at least one of the plurality of servers communicates with the fluid driver; and
determining whether a quantity of the at least one activation signal increases or decreases;
if yes, increasing or decreasing a flow rate of a coolant output by the fluid driver; and
if no, maintaining the flow rate of the coolant output by the fluid driver.

16. The liquid cooling control method according to claim 15, wherein the step of determining whether the quantity of the at least one activation signal increases or decreases comprises:
determining whether the quantity of the at least one activation signal increases;
if yes, increasing the flow rate of the coolant output by the fluid driver; and
if no, determining whether the quantity of the at least one activation signal decreases;
if yes, decreasing the flow rate of the coolant output by the fluid driver; and
if no, maintaining the flow rate of the coolant output by the fluid driver.

17. The liquid cooling control method according to claim 15, further comprising:
determining whether at least one power signal produced after the at least one of the plurality of servers is applied with electricity matches the at least one activation signal produced by the plurality of detectors when the liquid cooling unit of the at least one of the plurality of servers communicates with the fluid driver;
if yes, enabling the at least one of the plurality of servers to operate normally;
if no, stopping an operation of the at least one of the plurality of servers.

18. A rack module, comprising:
a rack;
a plurality of servers, slidably disposed in the rack; and
a liquid cooling system, disposed in the rack and comprising:
a fluid driver;
a plurality of liquid cooling units, disposed in the plurality of servers and selectively communicating with the fluid driver;
a plurality of detectors, configured to detect communication states of the plurality of liquid cooling units and the fluid driver, respectively; and
a controller, electrically connected to the fluid driver and the plurality of detectors, wherein the controller is configured to adjust a flow rate of a coolant output by the fluid driver according to the communication states.

19. The rack module according to claim 18, wherein the liquid cooling system further comprises a manifold, the plurality of liquid cooling units selectively communicate with the fluid driver via the manifold, and the plurality of detectors are respectively disposed on the plurality of liquid cooling units or are disposed on the manifold.

20. The rack module according to claim 18, wherein at least one of the plurality of detectors is configured to produce at least one activation signal when at least one of the plurality of liquid cooling units communicates with the fluid driver, and the controller is configured to adjust the flow rate of the coolant output by the fluid driver according to the at least one activation signal.
